(19) United States
(12) Patent Application Publication
(10) Pub. No.: US 2024/0213037 A1
(43) Pub. Date: Jun. 27, 2024

(54) METHOD FOR PRODUCING A STRUCTURE FOR STUD-BASED INTERCONNECTION BETWEEN MICROCIRCUITS

(71) Applicant: SHANGHAI HONGGAN MICROELECTRONICS TECHNOLOGY CO., LTD, Shanghai (CN)

(72) Inventor: Yang NI, PALAISEAU (FR)

(73) Assignee: SHANGHAI HONGGAN MICROELECTRONICS TECHNOLOGY CO., LTD, Shanghai (CN)

(21) Appl. No.: 18/557,292

(22) PCT Filed: Apr. 26, 2022
(86) PCT No.: PCT/IB2022/053844

§ 371 Date: Oct. 25, 2023

(30) Foreign Application Priority Data
Apr. 26, 2021 (FR) FR2104301

(51) Int. Cl. H01L 21/48

(52) U.S. Cl. CPC H01L 21/4857; H01L 21/4853

(57) ABSTRACT

The invention relates to a method for manufacturing an electronic circuit which uses CMOS technology, the method comprising: (a) a step of metal deposition (200) and etching to form metal connections (P, P′, . . . ) at a first level in a substrate, (b) a step of depositing a layer of dielectric material (110, . . . ) covering the metal connections, (c) a step of producing through-passages (112) in the thickness of the dielectric material, (d) a step of filling these passages with an interconnect metal (300), in order to form vias (V) connecting the levels. Steps (a) to (d) are repeated to form the metal connections (P, P′, . . . ) at different depths, connected by interconnection vias (V) in the thickness of the circuit.

### TECHNICAL FIELD

The present invention generally relates to a method for producing miniaturized interconnection networks based on protruding conductive micro-bumps, in particular in technologies for assembling flip-chip circuits.

### DESCRIPTION OF RELATED ART

It is known to produce a connection network between two circuits during their assembly one above the other. These connections can be very dense, and this technique is widely used today in electronic products such as display screens, integrated circuits with a very large number of inputs-outputs, and especially hybrid CCD/CMOS matrix image sensors.

To connect the connection points of the upper circuit to the connection points of the lower circuit, metal studs are made either on one of the two circuits, or on both, for example using one of the following techniques:
electroplating copper, lead or platinum, or various alloys;
solder balls on each stud: when the two circuits are brought into contact with a certain pressure and a high temperature, these balls melt, which allows erasure of any disparities in the height of the studs;
use of an ACA (Anisotropic Conductive Adhesive) type adhesive, namely an adhesive matrix wherein conductive beads are dispersed homogeneously: the density and the size of the conductive beads are chosen based on the pitch and the geometry of the interconnects so that at least one conductive bead is present in line with each stud; when the two circuits are assembled under high temperature, the pressure exerted thereupon deforms the beads and the studs and the adhesive is polymerized at the same time to attach the two circuits together;
progressive deformation studs, at a tip and typically of pyramidal shape, made of a metal of high ductility such as gold, for example: this allows the most protruding studs to be crushed by their vertex under the effect of the pressure applied during the contacting, the differences in height between the different studs thus being able to be absorbed within certain limits.

These techniques have demonstrated their effectiveness in the electronic assembly industry for a certain number of years.

However, they all require specific steps which are more or less complex to implement, and do not allow simultaneous production of studs for wire bonding.

### SUMMARY

The present invention aims to provide an industrially viable solution that can easily be integrated into a process for manufacturing CMOS circuits, to produce interconnections by means of protruding studs with very high densities on the one hand and, on the other hand, during the same steps, connecting studs for wire bonding during the integration of the circuits into a housing provided with connection elements.

To this end, proposed is a method for manufacturing an electronic circuit which uses CMOS technology, the method comprising:
(a) a step of metal deposition and etching to form metal connections at a first level in a substrate.
(b) a step of depositing a layer of dielectric material covering the metal connections.
(c) a step of producing through-passages in the thickness of the dielectric material,
(d) a step of filling these passages with an interconnect metal, in order to form vias connecting the levels.

Steps (a) to (d) being repeated to form the metal connections at different depths, connected by interconnection vias in the thickness of the circuit, the method being characterized in that it further comprises an iteration of step (a) in order to form, simultaneously:
a set of individualized conductive elements for the purposes of connecting said electronic circuit to homologous conductive studs of another circuit by bringing together and pressing the circuits, and
a set of connecting studs for bonding wires.

This method advantageously, but optionally, comprises the following additional features, taken individually or in any combination that a person skilled in the art will understand as being technically compatible with one another:
the conductive elements constitute interconnecting studs with homologous conductive studs of the other circuit.
the method further comprises, after the iteration of step (a):
   an iteration of steps (b) to (d) to form a set of individualized conductive elements topped by columns of said interconnect metal contained in a layer of dielectric material, and
   at least partially removing said layer of dielectric material so that said columns project from said layer and constitute protruding interconnecting studs with homologous conductive studs of the other circuit.
said interconnect metal is a refractory metal or a refractory metal-based alloy.
said interconnect metal is tungsten or a tungsten-based alloy.
the dielectric material is silicon dioxide.
the metal deposit constituting said metal connections comprises a main layer made of aluminum or cupro-aluminum and at least one secondary layer made of ceramic, such as titanium nitride, covering the main layer.
the method comprises a step of removing the secondary layer at the connecting studs.
the step of removing the secondary layer at the connecting studs is implemented before the iteration of step (a).
the step of removing the secondary layer at the connecting studs is implemented after the iteration of step (a).
the method comprises a step of removing the dielectric material and the material of the secondary layer at the connecting studs to form cavities where the main layer is exposed.
the method comprises a step of depositing an additional layer of dielectric material covering the columns before the step of removing the dielectric material and the secondary layer.

### BRIEF DESCRIPTION OF THE DRAWINGS

Other aspects, aims and advantages of the present invention will become more apparent on reading the following detailed description of preferred embodiments thereof, given by way of non-limiting example and with reference to the attached drawings. In the drawings:

FIG. 1 shows various steps implemented in a method for producing a conventional CMOS circuit,

FIG. 2 shows iterations of certain steps of a CMOS method for producing interconnecting studs with another circuit.

FIG. 2′ shows a variant of the steps of FIG. 2.

FIG. 3 is a microscopic photograph of an experimental interconnecting stud structure obtained with the method of FIG. 2,

FIG. 4 shows iterations of certain steps of a CMOS method for producing interconnection columns with another circuit,

FIG. 4′ shows a variant of the steps of FIG. 4, and

FIG. 5 is a microscopic photograph of an experimental interconnection column structure obtained with the method of FIG. 4.

### DESCRIPTION OF THE EMBODIMENTS

A high-density interconnection method and structure between two circuits according to the invention will now be described.

Most CMOS circuit manufacturing methods use aluminum as a connection layer base metal within a level and a refractory metal or alloy such as tungsten as metal for interconnecting the different levels.

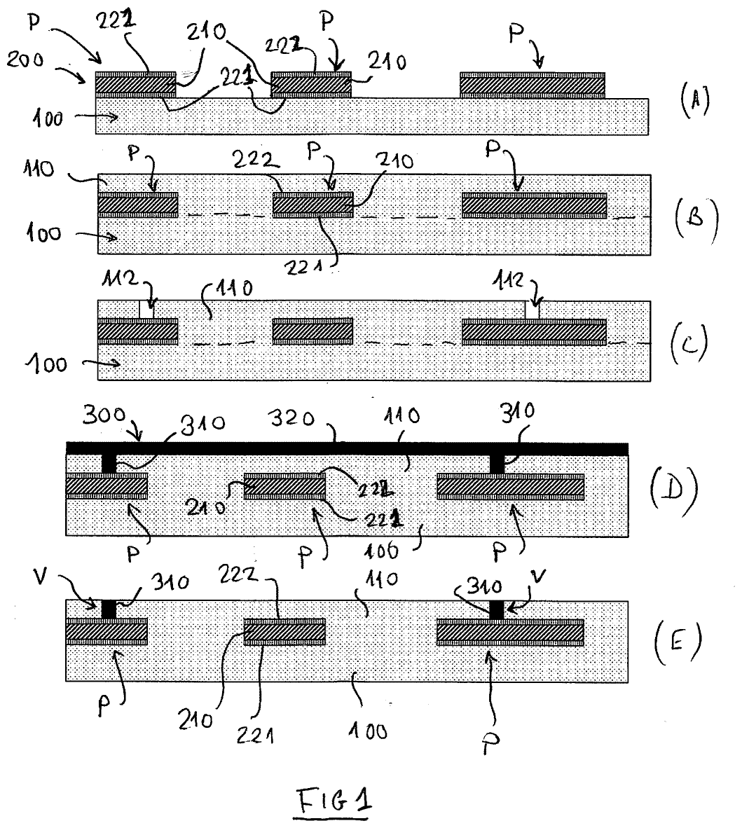

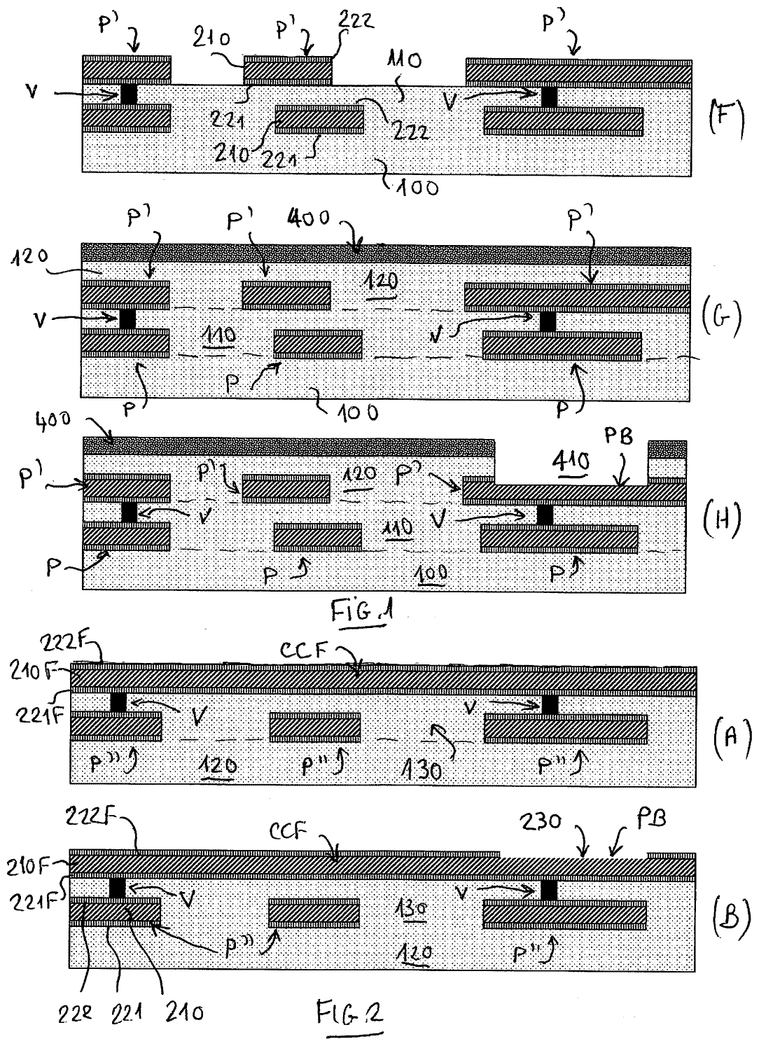

Referring first to FIG. 1, step (A) consists in producing, on a substrate made of dielectric insulating material 100, typically made of SiO₂, a layer 200 intended to form conductive tracks P at the same depth, this layer comprising three sandwiched sub-layers, namely, from bottom to top, a first layer 221 of ceramic material such as titanium nitride TiN forming an adhesion layer and diffusion barrier, a central layer 210 of aluminum-copper alloy with a high aluminum content (this will be referred to hereinafter as “aluminum layer” by convention), and second, upper layer 222 of ceramic material, here again for example TiN.

The following steps comprise a step of photolithography to define the patterns of the interconnection tracks P to be produced, followed by a step of selective etching of the zones left free by the photolithography.

Thus, as shown in part (A) of FIG. 1, conductive tracks P are produced above the substrate 100.

Step (B) consists in covering the assembly with another layer of dielectric insulating material 110, again made of SiO₂, which extends the layer 100 upward over a given thickness. This layer 110 undergoes a finishing by chemical mechanical polishing (CMP) in order to obtain a planar surface on the atomic scale.

The next step (C) consists in producing, in the layer of dielectric material 110, in positions that will determine the electrical connections between layers in the thickness of the substrate, holes 112 to a depth reaching the underlying conductive tracks P, by a conventional lithography and etching method.

In step (D), a layer of tungsten 300 is deposited so as to fill the holes in 310, overhanging in a continuous layer 320 above the free surface of the substrate 100.

In step (E), the excess tungsten constituting this continuous layer 320 is typically removed by chemical mechanical polishing, to leave only the parts 310 occupying the holes 112 and forming interconnection vias between conductive layers spaced apart in the thickness of the substrate (“W-Plug”).

The above steps are repeated with a step (F) of forming conductive tracks P′ of the following level and a step (G) of depositing a new layer 120 of dielectric insulating material, steps (C) to (E) being able to be repeated in a manner not shown to obtain a plurality of conductive layers of different levels and forming tracks P, P′, P″, P′″, suitably connected by vias V, V′, V″ between two successive layers separated by the electrical material.

In the present example, the tracks P′ are the last-level tracks, and step (G) also comprises depositing a passivation layer 400 to terminate the circuit. This layer 400 is typically composed of a layer of dielectric insulating material made of SiO₂ topped with a layer of silicon nitride SiN in order in particular to ensure protection against moisture.

In step (H), a lithography step and an etching step make it possible to produce cavities 410 by local removal of the layers 400 and 120 of dielectric material and of the ceramic layer 222, cavities wherein the metal or alloy of the underlying layer 210 is exposed to form connecting studs PB for connecting bonding wires, typically made of gold, with pins or other elements for connecting the circuit with the outside environment (“wire bonding”).

Removing the upper layer of TiN 222 is necessary here because its presence would prevent the bonding wire from being soldered.

One aspect of the present invention consists in relying on this conventional process for producing protruding studs for connection with another circuit to perform a hybridization, namely the very fine pitch connection for example between a CMOS circuit obtained by a process as explained above and a circuit, for example analog, more particularly a circuit of pixels accumulating photonic charges of photonic origin forming an image sensor, this in no way being limiting.

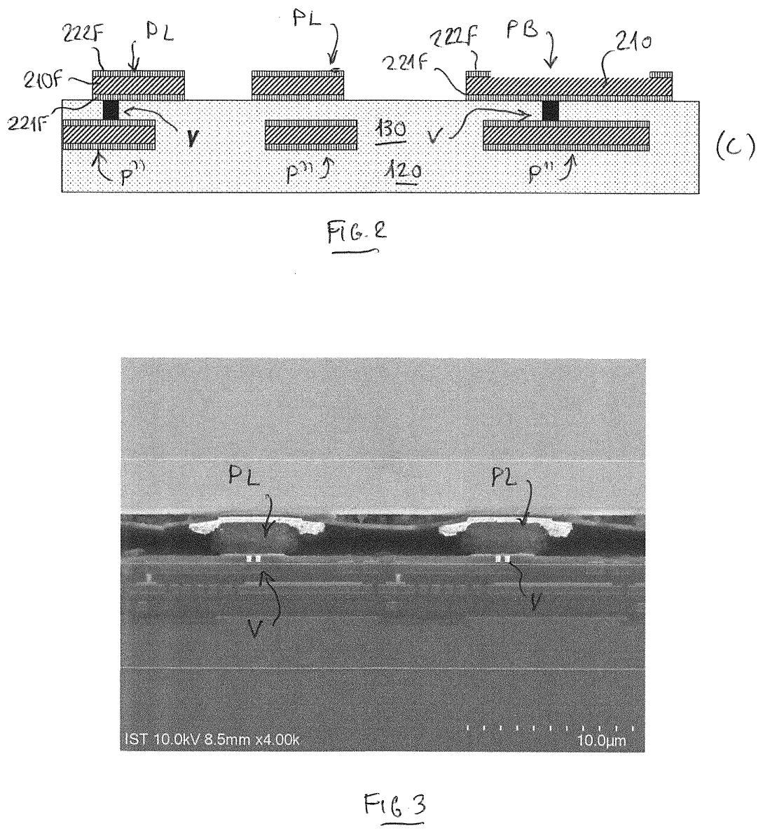

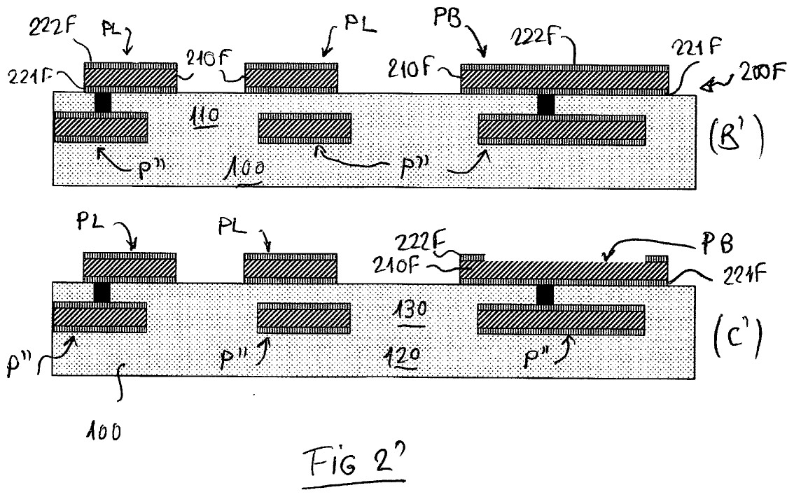

According to a first embodiment, and with reference now to FIG. 2, above the last layer of conductive tracks, here denoted P′, vias V have been produced in selected positions and a subsequent and final layer 200F of TiN/Al/TiN is applied to the layer 200 as described above, the three thicknesses of this layer being denoted 221F, 210F and 222F.

In step (B), the layer 222F of TiN is removed by selective etching to form areas 230 where the metal 210 is exposed and to form studs PB for bonding wires, generally arranged peripherally.

Then, in step (C), the combination of a photolithography and etching step makes it possible to selectively eliminate the layer 200F to leave, at the free surface of the substrate, a set of protruding studs PL for interconnection with another circuit, as well as the studs PB for bonding wires.

Thus, based on standard steps of the CMOS method, a circuit is produced which is provided on its free face on the one hand with studs PB for bonding wires, without the upper layer of TiN 222F, in order to allow the soldering of the wires, and on the other hand with protruding interconnection studs PL for the hybridization of the circuit with another circuit.

It will be noted here that the flatness of the hybridization studs PL here is excellent due to the nature of the steps implemented, and in particular due to the fact that the surface 110 whereupon the final metal layer 200F was deposited has been subject to chemical mechanical polishing and that the deposition of the layers 221F, 210F and 222 of the sandwich can be carried out with excellent thickness precision.

Moreover, the ceramic layer 222F, such as TiN, which covers each of the studs PL is known to have excellent chemical stability. Thus, even in the case where these studs PL are exposed before performing hybridization, their free surface is not subject to oxidation.

Referring now to FIG. 2′, we will describe a variant of the embodiment of FIG. 2. According to this variant, the steps of eliminating the upper layer 222F of TiN at the connecting stud PB and producing the protruding hybridization studs PL by lithography and etching are reversed. Thus, in step (B′) the photolithography and the etching have made it possible to delimit the connecting stud PB and the hybridization studs PL, while in step (C′) the upper layer 222F of TiN has been partially removed at the connecting stud PB to allow a bonding wire to be soldered.

It will be noted that the approach of FIG. 2 will generally be preferred, since in this case the steps of lithography and of etching to remove the layer 222F of the bonding studs are carried out on a flat surface, with easier and more effective spin-coating, whereas in the case of the approach of FIG. 2′ it is necessary to work with an irregular surface, which is more conducive to manufacturing defects.

FIG. 3 is a view by scanning electron microscopy (SEM) of a hybrid circuit with the pads produced according to the method of FIG. 2.

It will be understood that in the embodiments of FIGS. 2 and 2′, for a direct contact hybridization (without the addition of solder), the flatness of the protruding studs PL is critical. Thus, the mechanical and electrical assembly of the two circuits may require exposing the assembly to a relatively high pressure if the metal deposits of the layers 221F, 210F and 222F are not sufficiently uniform.

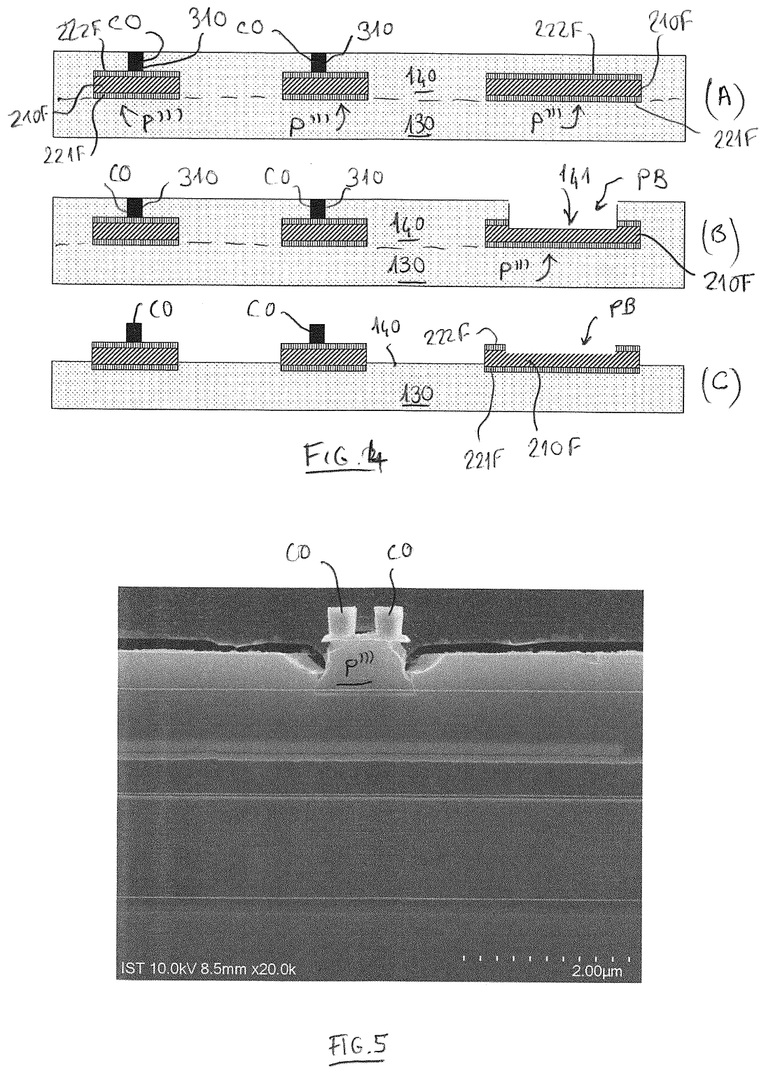

In another approach that will now be described with reference to FIG. 4, steps derived from those used in CMOS technology are again used to produce hybridization studs having a very good flatness and at the same time an excellent ability to compensate for the flatness defects of the other circuit.

In step (A), a set of conductive pads P′″ was produced at the last conductive layer, with two pads intended to be connected to hybridization studs and one pad intended to form a stud PB for welding bonding wire. Columns CO were also produced by the same process as that implemented to produce the vias V, above the two hybridization studs, by tungsten deposition to fill the cavities 112 formed in the last layer 140 of dielectric material (part 310 of the deposited metal) and overhang above the dielectric material (part 320 of the deposited metal), this latter part being removed by chemical mechanical polishing. The flatness of the free faces of the column CO vias is thus excellent. The pad intended to form a connecting stud PB is, for its part, entirely embedded in the dielectric insulating material 140.

In step (B), a cavity 141 is hollowed by lithography and etching above the connecting stud PB so as to remove the entire thickness of the dielectric material 140 as well as the upper layer 222F of TiN in order to thus expose the layer 210F whereupon a bonding wire can be soldered.

Finally, in step (C), a part of the thickness of the dielectric insulator 140 is removed, by dry etching or chemical etching, chosen to preserve the tungsten parts 310, so as to make the columns CO protrude above the remaining dielectric material and thus form narrow tungsten studs which protrude for the interconnection with the other circuit. This removal of the dielectric material 140 can be done up to an intermediate level between the upper face and the lower face of the conductive pads P′″. In this case, the etching conditions are also chosen to preserve the material of the layers 221F and 222F (typically TiN) and 210 (typically aluminum or aluminum alloy). For example, an etching with hydrofluoric acid vapor or BOE (“Buffered Oxide Etching”) type can be chosen.

As a variant, the conductive pads can be left entirely embedded in the dielectric material. In this case, the fact that the base of the columns CO is retained in the dielectric material may contribute to their mechanical robustness during the assembly of the two circuits.

The columns CO thus form very hard hybridization studs with a small cross section, at the same time with excellent flatness of their vertices, so as to produce quality contact with the other circuit during the contacting phase. Typically, the method described allows the vertices of the columns to deviate as much as possible by a distance of the order of 50 to 2000 nm from an “ideal” common plane.

It will be noted that the small cross section of the columns CO and their high hardness makes it possible to some extent to eliminate flatness defects at the contacts of the other circuit. Thus, when the two circuits are brought closer together in order to assemble them, by exerting a certain pressing force between them, the columns CO contact the contact pads of the other circuit, which are generally made with a more ductile metal. Because of the higher hardness of the metal or alloy of the columns CO relative to the metal or alloy of the pads of the other circuit, under the effect of the pressing each column which protrudes more than the others will be able to exert a local plastic deformation on the homologous conductive pad, partially embedding therein. It is thus guaranteed that the height differences inherent in the interconnection manufacturing method do not prevent some less protruding columns CO from coming into contact with their homologous conductive pad PC1, thus guaranteeing that all the electrical interconnections are made during this assembly.

A variant embodiment of this approach will now be described, intended to prevent the etching agents used to produce the cavity 141 above the connecting stud PB from being likely to damage the material, typically tungsten, constituting the parts 310.

This variant is shown in FIG. 4′. It consists of step (A′) of producing a layer of dielectric material 150 above the free layer obtained after the chemical-mechanical polishing which followed the deposition of tungsten.

The cavity 141 is then hollowed out in the layers 150 and then 140, also removing the layer 222F (step (B′)) to form the cavity, to obtain the same configuration of the connecting stud PB as in the case of FIG. 4.

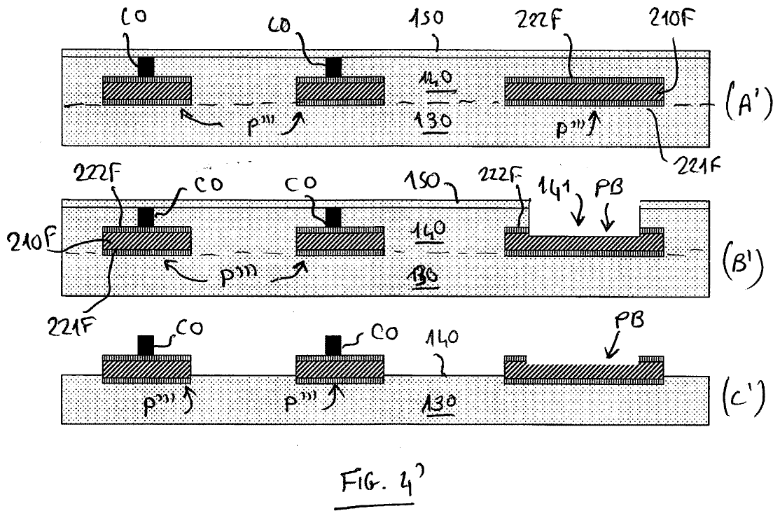

FIG. 5 shows, by way of illustration, a pad P′″ topped by two columns CO in scanning electron microscopy.

The present invention allows the production of high-density hybridization studs

According to a variant embodiment, it is possible to provide two or more columns CO in line with each pair of conductive pads of the other circuit. In particular, this makes it possible to further limit the cross section of each column and to facilitate the deformation of the pads of the other circuit when it is made necessary by overhanging columns relative to the ideal plane.

The permanent attachment of the circuits to one another can be carried out for example by applying an adhesive polymer interposed between the two circuits, or simply by molecular bonding owing to Van der Vals forces generated by a surface contact between the circuits.

In the first case, the method may comprise an additional step consisting in etching the trenches between the contact studs PL (FIGS. 2 and 2′) or the columns CO (FIGS. 4 and 4′), in particular to facilitate the emission of the excess adhesive, without the latter obstructing the correct assembly and the correct contact of the two circuits.

In the second case, an annealing step may be provided which is intended to reinforce the covalent bonds between the two surfaces and therefore the solidity of the assembly.

The methods according to each of the two approaches described above are advantageous in that they can be integrated very easily in a process for manufacturing circuits using CMOS technology, as explained.

For example, in a recent CMOS generation process in the 180 nm standard, the minimum dimension of the conductive pads and therefore of the hybridization studs PL in the embodiments of FIGS. 2 and 2′ is of the order of 0.28 μm, while the dimension of the inter-level contact vias and therefore of the columns CO in the embodiments of FIGS. 4 and 4′ is generally 0.24 μm to 0.28 μm.

In a particular example of a hybrid circuit, the conductive pads of the other circuit are made of gold. Since the Young's modulus of gold is 78 Gpa, then for a column having a cross section of 0.3 μm×0.3 μm, the insertion force necessary for each stud so as to compensate for the unevenness in height between the vertices of the columns can be estimated at 0.07 mN (millinewton). Thus, for a matrix of 1000×1000 studs, the total force necessary is only of the order of 70 N.

Alternatively, the conductive studs of the other circuit may be made of aluminum or copper. In the case of aluminum, its Young's modulus being 69 Gpa, the effect obtained in terms of force reduction is even better than that obtained for gold.

It is known that the behavior of the solder ball and pointed stud techniques of the prior art is sensitive to a parallelism error between the circuits connected together.

Thus, such a parallelism error can lead, before returning to parallel at the end of the assembly (due to the balancing of the forces), to excessively crushing the solder balls or pointed studs located near an edge of the circuits, and therefore to a defective contact.

With a structure where one of the two circuits has tungsten columns CO, it can be seen that when a column CO is completely embedded in the homologous conductive pad of the other circuit, the contacting of the layer of having a large dielectric material surface area of the circuit equipped with columns with the other circuit makes it possible to slow the mutual inclination of the two circuits and to induce self-restoration of the parallelism between the two circuits C1 and C2.

One of the most difficult problems in “flip-chip” technology with protruding studs, namely defective connections caused by the crushing of the marginal micro-studs due to a parallelism error as shown in FIG. 9, is thus eliminated.

The invention applies in particular to the assembly and connection of all circuits requiring high-density electrical connections, in particular hybrid circuits combining an analog circuit (for example but non-limitingly, an analog circuit of sensors accumulating charges of photonic origin) with a reading and processing circuit using CMOS technology.

1. A method for manufacturing an electronic circuit which uses CMOS technology, the method comprising:
(a) a step of metal deposition (200) and etching to form metal connections (P, P′, . . . ) at a first level in a substrate, the metal deposition (200) comprising a main layer (210, 210F) made of aluminum or cupro-aluminum and at least one secondary layer (222, 222F) made of ceramic, such as titanium nitride, covering the main layer,
(b) a step of depositing a layer of dielectric material (110, . . . ) covering the metal connections,
(c) a step of producing through-passages (112) in a thickness of the dielectric material,
(d) a step of filling these passages with an interconnect metal (300), in order to form vias (V) connecting the levels,
steps (a) to (d) are repeated to form the metal connections (P, P′, . . . ) at different depths, connected by interconnection vias (V) in a thickness of the circuit,
the method further comprises:
an iteration of step (a) in order to form, simultaneously:
a set of individualized conductive elements constituting interconnection studs (PL) of the electronic circuit with homologous conductive studs of another circuit by bringing together and pressing the circuits and direct solderless contact, and
a set of connecting studs (PB) for bonding wires, and
a step of eliminating the secondary layer (222F) at the connecting studs (PB).

2. (canceled)

3. The method according to claim 1, wherein it further comprises, after the iteration of step (a):
an iteration of steps (b) to (d) to form a set of individualized conductive elements (P′″) topped by columns (CO) of the interconnect metal (300) contained in a layer (140) of dielectric material, and
at least partially removing the layer (140) of dielectric material so that the columns project from the layer and constitute protruding interconnecting studs (CO) with homologous conductive studs of the other circuit.

4. The method according to claim 1, wherein the interconnect metal (300) is a refractory metal or a refractory metal-based alloy.

5. The method according to claim 4, wherein the interconnect metal is tungsten or a tungsten-based alloy.

6. The method according to claim 1, characterized in that the dielectric material (100, 110, . . . ) is silicon dioxide.

7. (canceled)

8. (canceled)

9. The method according to claim 1, wherein step of removing the secondary layer (222F) at the connecting studs is implemented before the iteration of step (a).

10. The method according to claim 1, wherein step of removing the secondary layer (222F) at the connecting studs is implemented after the iteration of step (a).

11. The method according to claim 3, wherein it comprises a step of removing the dielectric material and the material of the secondary layer at the connecting studs (PB) to form cavities (141) where the main layer (210F) is exposed.

12. The method according to claim 11, wherein it comprises a step of depositing an additional layer of dielectric material (150) covering the columns before the step of removing the dielectric material (140) and the secondary layer (222F).
